(19) United States
(12) Patent Application Publication
(10) Pub. No.: US 2020/0161830 A1
(43) Pub. Date: May 21, 2020

(54) DRIVER AND COMMUNICATION MODULE

(71) Applicant: FUJITSU COMPONENT LIMITED, Tokyo (JP)

(72) Inventor: Hideki Oku, Tokyo (JP)

(21) Appl. No.: 16/682,052

(22) Filed: Nov. 13, 2019

(30) Foreign Application Priority Data
Nov. 20, 2018 (JP) 2018-217431

(51) Int. Cl. H01S 5/042; H03K 5/13; H03H 7/06

(52) U.S. Cl. CPC H01S 5/0427; H03K 19/21; H03H 7/06; H03K 5/13

(57) ABSTRACT

A driver for outputting a drive signal to drive a direct-modulation semiconductor laser includes a compensation signal generator configured to produce a compensation signal that increases a drive current value at an end of a delay period following a positive transition of an “on” period of the drive signal during which an “on” state continues.

### FIELD

The disclosures herein relate to a driver and a communication module.

### BACKGROUND

Optical communication uses an optical module that connects an optical cable to a communication device. The optical module drives a semiconductor laser to convert an electrical signal output from the communication device into an optical signal for output to the optical cable.

When a semiconductor laser is driven through direct modulation, the waveform of an optical signal from the semiconductor laser deteriorates due to the effect of relaxation vibration of the semiconductor laser. Technology has been developed that compensates for the deterioration of an optical signal (see Patent Documents 1 and 2).
[Patent Document 1] Japanese Patent Application Publication No. 9-312611
[Patent Document 2] Japanese Patent Application Publication No. 2015-144326

### SUMMARY

The inventor of the present invention has found that an optical signal deteriorates with a dip in the waveform due to the effect of relaxation vibration of a semiconductor laser when the optical signal output from the semiconductor laser has multiple consecutive bits in the “on” state. However, technology in the related art cannot compensate for the waveform degradation of an optical signal that occurs upon the occurrence of multiple consecutive bits in the “on” state.

In order to solve the above-noted problems, a driver for outputting a drive signal to drive a direct-modulation semiconductor laser includes a compensation signal generator configured to produce a compensation signal that increases a drive current value at an end of a delay period following a positive transition of an “on” period of the drive signal during which an “on” state continues.

### BRIEF DESCRIPTION OF DRAWINGS

FIG. 1 illustrates a driver according to the embodiment;

FIG. 2 illustrates a high-pass filter;

FIG. 3 illustrates the configuration of a gate;

FIG. 4 is a signal timing chart with respect to the driver;

FIG. 5 illustrates a driver according to a first variation;

FIG. 6 is a signal timing chart with respect to the driver of the first variation;

FIG. 7 illustrates a driver according to a second variation;

FIG. 8 is a signal timing chart with respect to the driver of the second variation;

FIG. 9 illustrates a driver according to a third variation;

FIG. 10 is a signal timing chart with respect to the driver of the third variation; and

FIG. 11 illustrates a communication system.

### DESCRIPTION OF EMBODIMENTS

In the following, embodiments of the invention will be described with reference to the accompanying drawings.

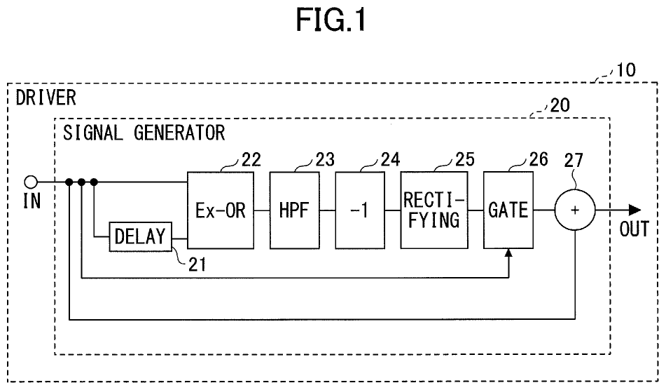

FIG. 1 illustrates a driver 10 according to an embodiment. The driver 10 is a circuit that drives a direct-modulation semiconductor laser (hereinafter referred to as a “laser”). The driver includes a signal generator 20 for producing a compensation signal that temporarily increases a drive current value upon passage of a predetermined time after the positive transition of a drive signal when multiple consecutive bits in the drive signal are in the “on” state. With this arrangement, the driver 10 outputs a drive signal that compensates for the degradation of an optical signal creating a dip in the waveform due to relaxation vibration that occurs when the “on” state continues for multiple bits.

As illustrated in FIG. 1, the signal generator 20 includes, in the following order from the input side, a delay circuit 21, an exclusive-OR circuit (hereinafter referred to as “EOR”) 22, a high-pass filter (hereinafter referred to as “HPF”) 23, an inverting circuit 24, a rectifying circuit 25, a gate 26, and an adder 27. A drive signal is input into the signal generator 20 from a terminal IN and output from a terminal OUT.

The delay circuit 21 outputs a delay signal obtained by delaying the drive signal input from the terminal IN by 1 bit. The delay time in this embodiment is set to 1 bit, but this is not limiting. The delay time may properly be set based on the results of tests and simulations in accordance with the position of a dip in the degraded waveform. The delay circuit 21 may be designed such that the delay time is changeable.

The EOR 22 outputs an exclusive disjunction (i.e., exclusive or) of the drive signal and the delay signal.

The HPF 23 extracts and outputs high frequency components from the output signal of the EOR 22.

The inverting circuit 24 outputs an inverted signal obtained by inverting the polarity of the output signal of the HPF 23.

The rectifying circuit 25 rectifies the output signal of the inverting circuit 24 to remove the negative components from the output signal of the inverting circuit 24, thereby outputting a high frequency component signal having only positive values.

The gate 26 outputs the high frequency component signal that is input from the rectifying circuit 25 when the drive signal is “on”.

The adder 27 adds the output of the gate as a compensation signal to the input drive signal, followed by outputting the result of the addition. The output signal of the adder 27 is output from the terminal OUT as a laser drive signal.

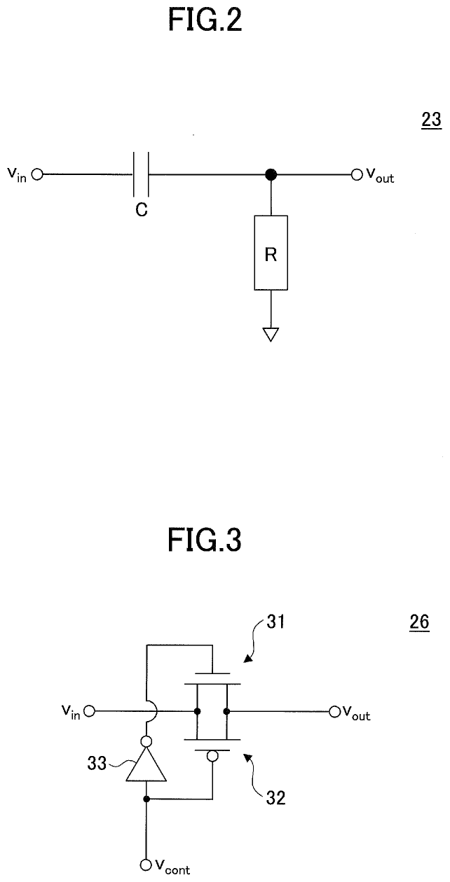

FIG. 2 illustrates the HPF 23 according to the embodiment. The HPF 23 includes a capacitor C and a resistor R. The capacitor C has one end coupled to an input terminal Vin and the other end coupled to an output terminal Vout. The resistor R has one end coupled to a point between the capacitor C and the output terminal Vout. The cutoff frequency fc of the HPF23 illustrated in FIG. 2 is obtained by formula (1).

fc=1/(2πCR) (1)

FIG. 3 illustrates the gate 26 according to the embodiment. The gate 26 includes an n-channel MOSFET 31, a p-channel MOSFET 32, and a NOT circuit 33, all of which constitute a CMOS transfer gate circuit.

In the gate 26, the source and drain of the MOSFET 31 and the source and drain of the MOSFET are connected in parallel between the input terminal Vin and the output terminal Vout.

The gate of the MOSFET 32 receives a gate voltage Vcont. The gate of the MOSFET 31 receives an inverted version of the gate voltage Vcont output from the NOT circuit 33.

The gate 26 operates such that the input terminal Vin and the output terminal Vout are coupled to each other when the gate voltage Vcont is low, and the input terminal Vin and the output terminal Vout are not coupled to each other when the gate voltage Vcont is high.

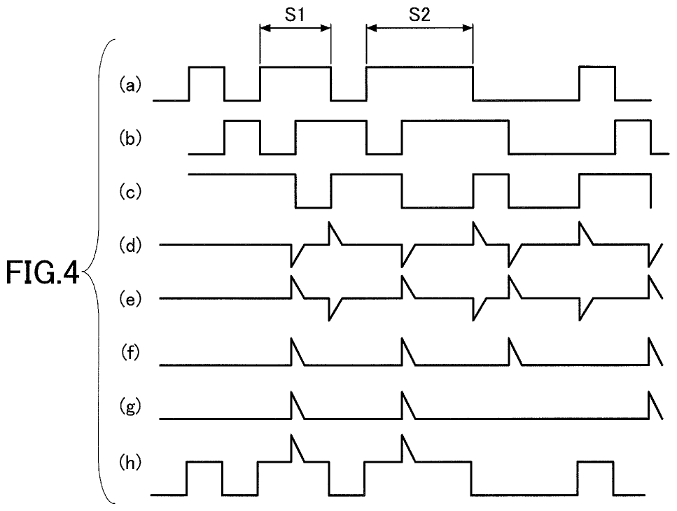

FIG. 4 is a signal timing chart with respect to the driver 10.

The signal (a) illustrates a drive signal that is input into the signal generator 20. The drive signal (a) is a pulse signal whose “on” state drives a laser. The drive signal (a) has “on” periods S1 and S2 each of which is constituted by multiple consecutive bits in the “on” state.

The signal (b) is a delay signal obtained by delaying the drive signal (a) by 1 bit and output from the delay circuit 21. The signal (c), which is the output of the EOR 22, is an exclusive disjunction of the drive signal (a) and the delay signal (b).

The signal (d), which is the output of the HPF 23, corresponds to high frequency components extracted from the signal (c). The output signal (d) of the HPF 23 drops to a negative level at the negative transition of the signal (c), and rises to a positive level at the positive transition of the signal (c).

The signal (e), which is the output of the inverting circuit 24, is an inverted version of the signal (d). The signal (f), which is the output of the rectifying circuit 25, is a signal obtained by removing negative waveforms from the signal (e). The signal (g), which is the output of the gate 26, is the signal (f) appearing only during the “on” periods of the drive signal (a).

The signal (h), which is the output of the adder 27, is obtained by adding the signal (g) as a compensation signal to the drive signal (a). The signal (h) has a drive current value that exhibits a temporal increase at the end of a 1-bit period immediately following the positive transition of the drive signal for each of the “on” periods S1 and S2. This is based on the finding made by the inventor that a dip in the deteriorated waveform occurs at the end of a 1-bit period immediately following the positive transition of a drive signal when the “on” state continues for multiple bits. The driver 10 uses the signal (h) to drive a laser, thereby compensating for the deterioration of an optical signal waveform caused by relaxation vibration.

As described above, the driver 10 includes the signal generator 20 for producing a compensation signal that increases the drive current value at the end of a 1-bit period after the positive transition of a drive signal, with respect to an “on” period of the drive signal constituted by multiple consecutive “on”-state bits. The driver 10 uses the compensated drive signal to drive a laser, thereby compensating for the deterioration of an optical signal waveform caused by relaxation vibration when the “on” state continues for multiple bits.

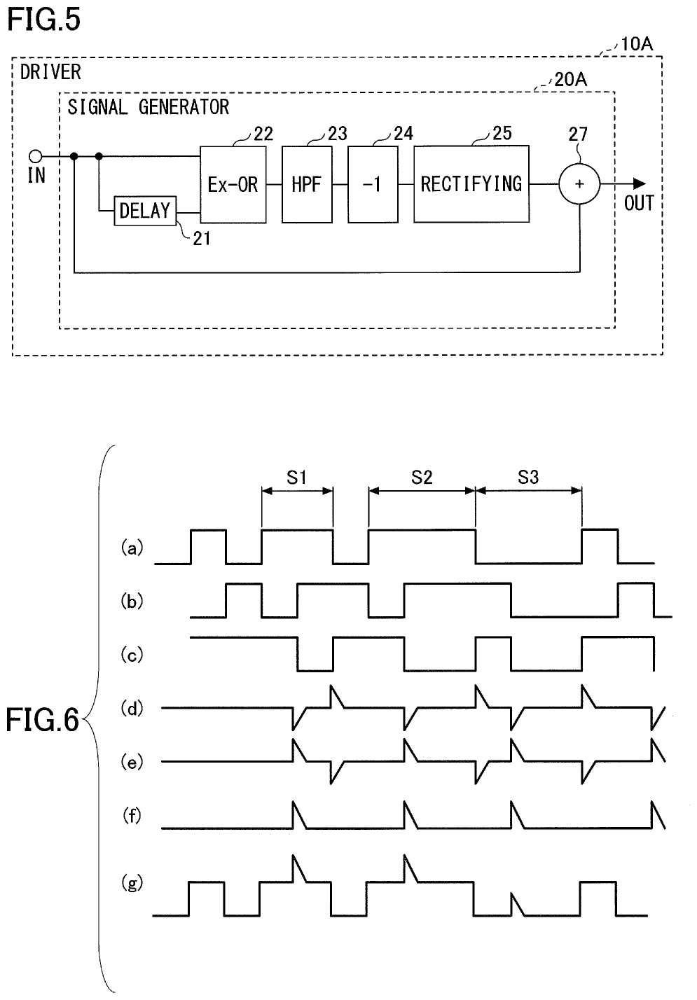

FIG. 5 illustrates a driver 10A according to a first variation. A signal generator 20A of FIG. 5 does not have a gate, and the output signal of the rectifying circuit 25 is input into the adder 27 as a compensation signal to be added to the drive signal.

FIG. 6 is a signal timing chart with respect to the driver 10A. The signals (a) to (f) in FIG. 6 correspond to the signals (a) to (f) in FIG. 4. The signal (g) of FIG. 6, which is the output of the adder 27, is obtained by adding the signal (f) from the rectifying circuit 25 to the drive signal (a).

Since the driver 10A does not have a gate 26, the signal (f) is added to the drive signal (a) even during the “off” period S3 in which the “off” state continues for multiple bits as illustrated in FIG. 6. However, the signal (f) has a relatively small current value, and the laser has a narrow frequency band, so that the signal (f) does not appear in the optical signal output from the laser. The addition of the signal (f) to the drive signal (a) during the “off” period S3 thus does not affect the quality of an optical signal. In addition, the absence of a gate simplifies the circuit.

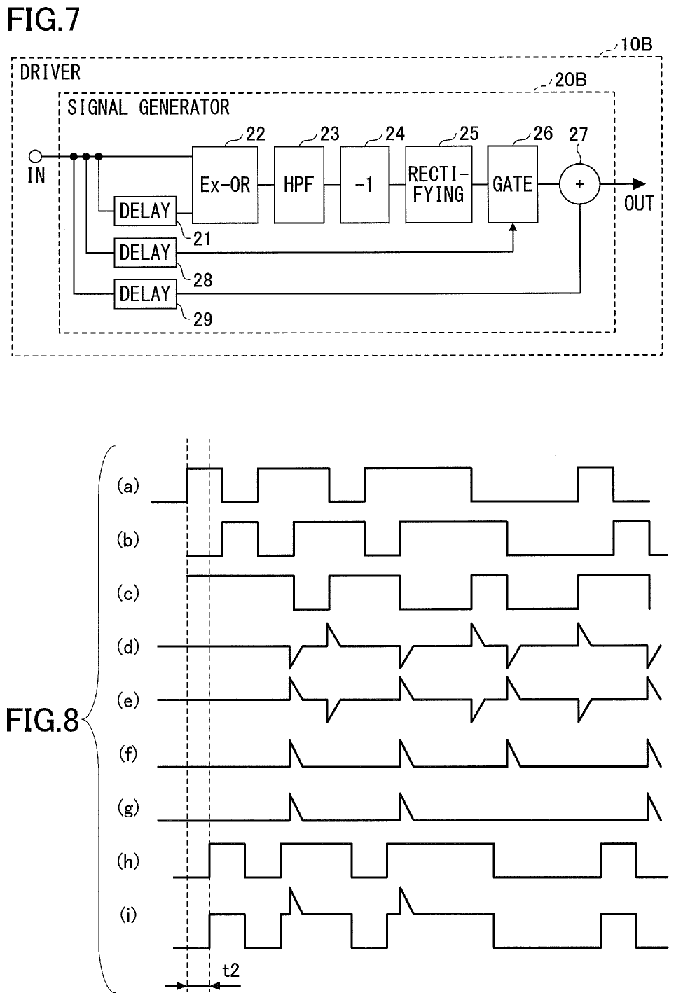

FIG. 7 illustrates a driver 10B according to a second variation. The driver 10B includes a signal generator 20B having delay circuits 28 and 29.

The delay circuit 28, which is an example of a “third delay circuit”, outputs to the gate 26 a delay signal obtained by imposing a delay t3 on the drive signal input at the input terminal IN. The gate 26 uses the output of the delay circuit 28 to extract and remove, from the output signal of the rectifying circuit 25, components overlapping the “off” periods of the drive signal that is delayed by t3.

In FIG. 1, the signal input into the gate 26 is delayed by a path between the EOR 22 and the rectifying circuit 25. On the other hand, the drive signal supplied from the input terminal IN to the adder 27 is not delayed, so that the output signal of the gate 26 and the drive signal input into the adder 27 may be misaligned in the circuit of FIG. 1. In order to compensate for this misalignment, the delay circuit 28 delays the drive signal. The delay time t3 is preferably set equal to the delay time imposed on a signal along the path from the input terminal IN to the gate 26. This allows the gate 26 to receive the drive signal and the output signal of the rectifying circuit 25 simultaneously, thereby allowing the gate 26 to perform signal extraction and removal with high accuracy.

The delay circuit 29, which is an example of a “second delay circuit”, outputs to the adder 27 a delay signal obtained by imposing a delay t2 on the drive signal input at the input terminal IN. The adder 27 outputs a drive signal that is the sum of the drive signal from the delay circuit 29 and the signal output from the gate 26.

As in the case of the delay circuit 28, the delay time t2 of the delay circuit 29 is preferably set equal to the delay time of the path from the input terminal IN to the adder 27. With this arrangement, the same delay time is given to both the drive signal and the high-frequency component signal input into the adder 27, which increases the accuracy of adding a compensation signal to the drive signal at the adder 27.

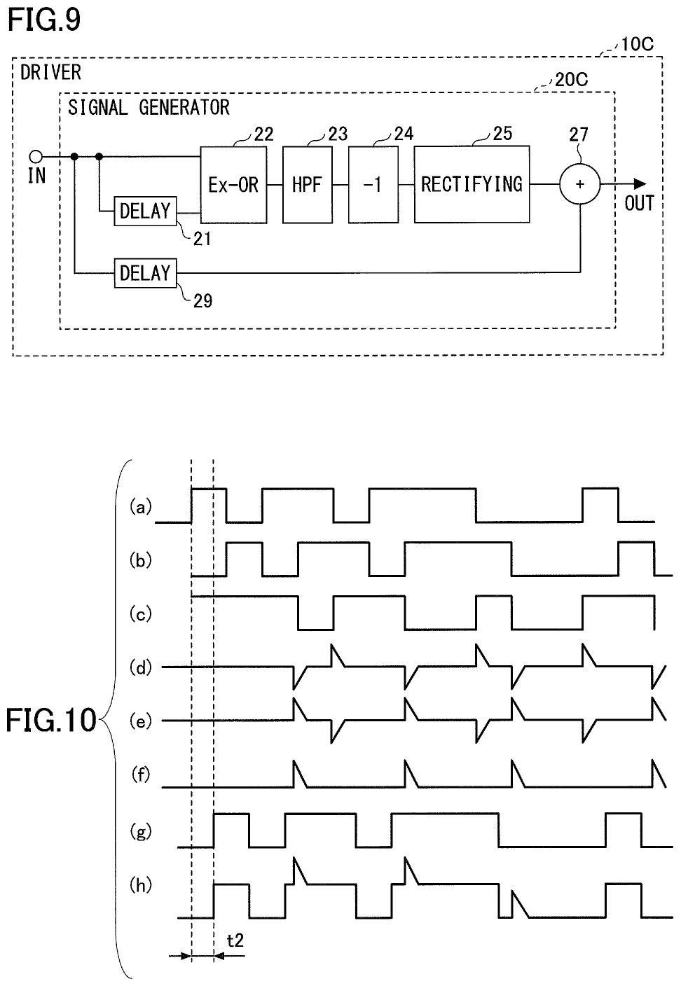

FIG. 8 is a signal timing chart with respect to the driver 10B. The signals (a) to (g) in FIG. 8 correspond to the signals (a) to (g) in FIG. 4. The signal (h) of FIG. 8 is the output of the delay circuit 29. The signal (i) of FIG. 8, which is the output of the adder 27, is the sum of the signal (g) and the signal (h). Delaying the drive signal by the use of the delay circuit 29 allows input timing at the adder 27 to be aligned between the signal (g) and the signal (h). Although the waveform is not illustrated in FIG. 8, the use of the delay circuit allows input timing at the gate 26 to be also aligned between the signal (f) and the drive signal.

FIG. 9 illustrates a driver 100 according to a third variation. The signal generator 20C of FIG. 9 has neither the gate 26 nor the delay circuit 28, so that the signal output from the rectifying circuit 25 is directly input into the adder 27 to be added to the output of the delay circuit 29.

FIG. 10 is a signal timing chart with respect to the driver 100. The signals (a) to (f) in FIG. 10 correspond to the signals (a) to (f) in FIG. 8. The signal (g) of FIG. 10 is the same as the signal (h) of FIG. 8. The signal (h) of FIG. 10 is the output signal of the adder 27.

In the driver 100 without the gate 26, the high-frequency component signal is added to the drive signal even during the “off” period of the drive signal as illustrated in FIG. 10. However, the signal (f) has a relatively small current value, and the laser has a narrow modulation frequency band, so that the signal (f) output during the “off” period does not appear in the optical signal output from the laser. Accordingly, the circuit configuration is simplified for the driver 100 without affecting the transmission quality of optical signals.

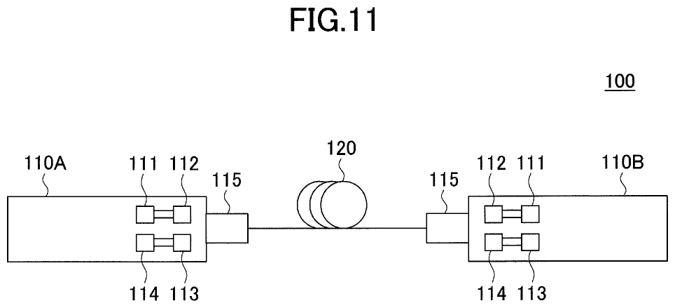

FIG. 11 illustrates the configuration of a communication system 100 according to an embodiment. In the communication system 100 illustrated in FIG. 11, a pair of optical modules 110 (110A and 110B) are connected through an optical cable 120. The optical modules 110, which are used in communication for a supercomputer or the like, are connected the optical cable 120 to transmit and receive optical signals. The optical modules 110 convert electrical signals from communication devices into optical signals for transmission to the optical cable 120, and convert optical signals from the optical cable 120 into electrical signals for output to the communication devices.

Each of the optical modules 110 includes a driver 111, a laser 112, a photodiode (PD) 113, a TIA (trans-impedance amplifier) 114, and an optical connector 115. The driver 111 drives the laser 112 in response to electrical signals received from the communication device. Implementing the driver 111 as the driver 10, 10A, 10B, or 100 described in the embodiment and variations allows the outputting of a drive signal to compensate for the deterioration of optical signal waveforms caused by relaxation vibration that occurs when the “on” state continues for multiple bits, thereby preventing the deterioration of transmission quality. The laser 112 is driven through direct modulation by the drive signal supplied from the driver 111 to emit laser light in accordance with an electrical signal supplied from the communication device. In this embodiment, VCSEL (vertical-cavity surface-emitting laser) is used as the laser 112. The laser light emitted from the laser 112 is directed to the optical cable 120 connected to the optical connector 115. The PD 113 receives laser light from the optical cable 120, and converts the laser light into an electrical signal. The TIA 114 converts the current signal output from the PD 113 into a voltage signal.

Although the embodiment of the present invention has been described, the present invention is not limited to such an embodiment, but various variations and modifications may be made without departing from the scope of the present invention as set forth in the claims.

The driver is not limited to the configuration described in the embodiment. The driver may be implemented as any circuit configuration as long as a compensation signal can be generated to temporarily increase the drive current value upon passage of a delay time following the positive transition of an “on” period during which the drive signal is continuously in the “on” state for multiple bits.

The present application is based on and claims priority to Japanese patent application No. 2018-217431 filed on Nov. 20, 2018, with the Japanese Patent Office, the entire contents of which are hereby incorporated by reference.

What is claimed is:

1. A driver for outputting a drive signal to drive a direct-modulation semiconductor laser, comprising a compensation signal generator configured to produce a compensation signal that increases a drive current value at an end of a delay period following a positive transition of an “on” period of the drive signal during which an “on” state continues.

2. The driver as claimed in claim 1, wherein the compensation signal generator includes:
a delay circuit configured to produce a delay signal made by delaying the drive signal;
an exclusive-or circuit configured to output an exclusive disjunction of the drive signal and the delay signal to produce an exclusive-or signal;
a filter configured to extract high-frequency components from the exclusive-or signal to produce a high-frequency-component signal;
an inverting circuit configured to invert a polarity of the high-frequency-component signal extracted by the filter to produce a polarity-inverted high-frequency-component signal;
a rectifying circuit configured to extract positive-level waves from the polarity-inverted high-frequency-component signal produced by the inverting circuit to produce a rectified high-frequency-component signal; and
an adder configured to add the compensation signal to the drive signal, the compensation signal being the rectified high-frequency-component signal produced by the rectifying circuit.

3. The driver as claimed in claim 2, wherein the compensation signal generator further includes a second delay circuit configured to delay the drive signal input into the adder.

4. The driver as claimed in claim 2, wherein the compensation signal generator further includes a gate configured to remove a portion of the rectified high-frequency-component signal produced by the rectifying circuit, the portion corresponding to a period other than any of the “on” period of the drive signal.

5. The driver as claimed in claim 4, wherein the compensation signal generator further includes a third delay circuit configured to delay the drive signal input into the gate.

6. A communication module for performing optical communication through an optical cable, comprising:
the driver of claim 1; and
a semiconductor laser configured to be driven by the drive signal supplied from the driver to which the compensation signal is added, and configured to transmit an optical signal responsive to the drive signal to the optical cable.
